(19) United States
(12) Patent Application Publication
(10) Pub. No.: US 2021/0242314 A1
(43) Pub. Date: Aug. 5, 2021

(54) METHODS OF MANUFACTURING A GRAPHENE-BASED DEVICE

(71) Applicant: THE UNIVERSITY OF MANCHESTER, Manchester (GB)

(72) Inventors: Max MIGLIORATO, High Peak, Derbyshire (GB); Rakesh KUMAR, Manchester, Greater Manchester (GB); Umberto MONTEVERDE, Manchester, Greater Manchester (GB)

(21) Appl. No.: 16/972,545

(22) PCT Filed: Jun. 4, 2019
(86) PCT No.: PCT/GB2019/051543

§ 371 Date: Dec. 4, 2020

(30) Foreign Application Priority Data
Jun. 5, 2018 (GB) 1809160.3

(51) Int. Cl. H01L 29/16; H01L 21/02; C01B 32/186

(52) U.S. Cl. CPC H01L 29/1606; B82Y 30/00; C01B 32/186; H01L 21/02527

(57) ABSTRACT

A method of manufacturing a graphene-baseddevice, comprising (i) providing a graphene assembly comprising one or more layers of graphene, a first photoresist layer disposed on the one or more layers of graphene, and an ultra-violet (UV) barrier layer disposed on the photoresist layer on an opposite side to the one or more layers of graphene; (ii) transferring the graphene assembly onto a substrate comprising at least one cavity so that the one or more layers of graphene traverse the at least one cavity; (iii) using photolithography to expose portions of the one or morelayers of graphene on opposite sides of the at least one cavity;(iv) forming conductive contacts over the exposed portions of graphene; (v) removing the UV barrier layer; and (vi) removing the first photoresist layer.

This invention relates to methods of manufacturing a graphene-based device where, in particular, the graphene-based device includes one or more layers of graphene that each traverse a cavity formed in a substrate.

### BACKGROUND

Graphene, a single atom thick 2D monolayer layer of carbon atoms, with its extraordinary physicochemical properties, high surface area (˜2630 m2g-1), thermal conductivity (˜5000 W/mK), electrical conductivity (mobility >15000 to 200,000 cm2V-1s-1) and mechanical strength (yield strength; ˜130 GPa, Young's modulus; 1 TPa) offers huge potential for use in sensor applications such as biosensors and chemical sensors. Since graphene does not have band gap, graphene needs to be modified (e.g. chemically or physically strained) to create a bandgap similar to that possessed by many semiconductor materials, and make the graphene suitable for use in electronic devices (such as switching devices, for example). Given that every atom in graphene is a surface atom, the graphene surface is ultrasensitive to any adsorbents (biological or gas molecules). Adsorption on the surface of graphene quickly changes its electronic or chemical properties. Consequently, graphene-based devices are attractive candidates for biological and/or chemical sensor applications.

A suspended graphene sheet, in particular, possess an ultrahigh electron mobility and very high surface reactivity due to there being no charge transport (or distribution) interferences from the supporting substrate. Introducing a controlled tensile or compressing stress can further modify the electronics properties of a suspended graphene sheet. The term “suspended graphene” is used to refer to one or more layers of graphene that each traverse a cavity formed in a substrate.

Graphene-based sensors are particularly advantageous over carbon nanotube (CNT) and carbon nanofiber (CNF)-based sensors as graphene can be produced with a large surface area relatively inexpensively. In particular, high-quality monolayer graphene can be produced on a large scale (e.g. by chemical vapour deposition (CVD)) and such graphene is comparatively easier to process (in contrast to CNT and CNFs) and possesses anti-fouling and non-toxic properties. Such properties make graphene-based devices attractive for measuring characteristics of environmental air including gas and/or volatile organic compounds (VOCs) monitoring.

There is an increasing demand for air quality monitoring solutions, both indoors and outdoors. VOCs are emitted from solids or liquids with high vapor pressure and are often combustible and toxic leading to damaging affects on public health. Therefore, the capability of on-site real-time monitoring is highly sought after. Currently, photoionization detectors (PIDs) are used for VOC monitoring. PID devices are bulky and expensive to make, however. As such, there is a need for more portable and less expensive methods for detecting VOCs.

That being said, there are challenges in producing graphene-based devices, particularly on a large scale. As an example, the fabrication techniques often employed in the manufacture of electronic components may damage or otherwise render the graphene less (or not at all) functional. This is particularly true of devices that utilize suspended graphene, not least because the graphene is necessarily unsupported by the substrate in certain places. Additionally, when monolayer graphene is laid over any solid insulating surface, its electronic properties are severely affected due to surface interactions and surface contaminations, which eventually reduce the dynamic sensitivity and other advantageous properties associated with graphene. There is therefore a need to develop methods that enable the fabrication and/or improve the yield of graphene-based devices that include suspended graphene.

It is an object of certain embodiments of the present invention to overcome at least some disadvantages associated with the prior art.

### BRIEF SUMMARY OF THE DISCLOSURE

In accordance with an aspect of the present invention there is provided a method of manufacturing a graphene-based device, comprising:
providing a graphene assembly comprising one or more layers of graphene, a first photoresist layer disposed on the one or more layers of graphene, and an ultra-violet (UV) barrier layer disposed on the first photoresist layer on an opposite side to the one or more layers of graphene;
transferring the graphene assembly onto a substrate comprising at least one cavity so that the one or more layers of graphene traverse the at least one cavity;
using photolithography to expose portions of the one or more layers of graphene on opposite sides of the at least one cavity;
forming conductive contacts over the exposed portions of graphene;
removing the UV barrier layer; and
removing the first photoresist layer.

The UV barrier layer provides a desirable UV shielding effect, thereby serving to protect the underlying layer of graphene from UV radiation (employed as part of photolithography operations) during fabrication of the device. The presence and removal of the UV barrier layer does not unduly affect the layer of graphene during fabrication. Such protection affords a higher yield of successfully fabricated areas of suspended graphene (i.e. graphene that traverses at least one cavity) on a substrate, and therefore lends itself to the production of a device that includes a large array of suspended layers of graphene.

In certain embodiments, the UV barrier layer comprises one or more metals, e.g. aluminium, chromium, gold, and silver. An aluminium UV barrier layer not only provides the desired UV protection, but it also serves to provide additional mechanical strength and mechanical shielding to the layer of graphene (and possibly other parts of the device) during fabrication. Similarly, other metal UV barrier layers (including but limited to those listed above) may also provide additional mechanical strength to the device during fabrication.

The step of providing the graphene assembly may comprise providing a precursor graphene assembly, wherein the precursor graphene assembly comprises the graphene assembly and a layer of copper disposed on a side of the one or more layers of graphene that is opposite to the first photoresist layer, and wherein the layer of copper is removed to provide the graphene assembly. For example, the precursor graphene assembly may be formed by chemical vapour deposition (CVD) of graphene on the layer of copper. CVD graphene is particularly suitable for use in the methods of the present invention. CVD graphene may advantageously be deposited on a large scale over a metal surface, thereby making it particularly suitable for device fabrication. In particular, CVD graphene is particularly compatible with microfabrication equipment and processes employed in the semiconductor industry, and may readily be transferred onto a substrate such as silicon.

The method may additionally comprise wet etching to remove the layer of copper to provide the graphene assembly.

The precursor graphene assembly may further comprise one or more sacrificial layers of graphene disposed on a side of the layer of copper that is opposite the one or more layers of graphene, and the method may further comprise removing the one or more sacrificial layers of graphene prior to removing the layer of copper. The sacrificial layer of graphene may arise from a CVD process whereby graphene is deposited on opposite sides of the layer of copper. Typically, the sacrificial layer of graphene will be of a lower quality than the layer of graphene to be used in the final device. The sacrificial layer of graphene may be the inevitable (but redundant) layer of graphene that is formed on a metal surface (e.g. Cu) during a CVD process (in addition to the intentionally deposited layer of graphene that is to be used). The sacrificial layer may not be continuous and/or homogenous.

The graphene may be substantially pure graphene (e.g. produced by CVD, exfoliation or otherwise), oxidized graphene (otherwise known as oxygenated graphene or graphene oxide), graphane (i.e. fluorinated graphene) and any other chemically functionalized graphene. The derivatives of graphene may be formed by modifying the layer of graphene 32 whilst it is on the precursor graphene assembly 32 or when it forms part of a final device, or indeed at any suitable stage in the intermediate fabrication process.

The method may comprise plasma etching to remove the one or more sacrificial layers of graphene.

In certain embodiments, the substrate may comprise one or more of Si, SiO₂, SU8 polymer, sapphire or a semiconductor material. SU8 is a polymer that may advantageously be lithographically patterned to create cavities. SU8 is advantageously flexible, has high stability and is compatible with aqueous solutions.

The step of using photolithography to expose portions of the graphene on opposite sides of the at least one cavity may comprise disposing a second photoresist layer on the UV barrier layer, using a photomask to lithographically pattern the second photoresist layer so that second photoresist layer remains on the UV barrier layer whilst exposing portions of the UV barrier layer on opposite sides of the at least one cavity, removing the exposed portions of the UV barrier layer so as to expose portions of the first photoresist layer on opposite sides of the at least one cavity and leave remaining UV barrier layer traversing therebetween, removing the exposed portions of the first photoresist layer so as to expose the portions of the one or more layers of graphene and leave remaining first photoresist layer traversing therebetween. The step of removing the exposed portions of the UV barrier layer may be performed using wet etching.

The step of removing the exposed portions of the first photoresist layer may be performed using photolithography.

The step of forming conductive contacts may comprise depositing conductive material onto the exposed portions of graphene by thermal evaporation. The conductive material may comprise a layer of a first conductive material and a layer of a second conductive material. In certain embodiments, the first conductive material may comprise Cr and/or the second conductive material may comprise Au.

The method may further comprise using a third photoresist layer to mask the conductive material deposited on the exposed potions of graphene, removing any other deposited conductive material, and lithographically removing the third photoresist layer prior to removing the UV barrier layer. The step of removing any other deposited conductive material may be performed using wet etching.

The step of removing the UV barrier may be performed using wet etching. Wet etching of the UV barrier layer may be performed using phosphoric nitric acetic acid. In certain embodiments, the phosphoric nitric acetic acid may contain 80 wt % phosphoric acid, 5% nitric acid, 5% acetic acid, and 10% distilled water.

In certain embodiments, removing the first photoresist layer is performed using critical point drying. In alternative embodiments, other methods of removing the first photoresist layer may be employed. For example, the device may be immersed in a solvent (e.g. acetone) which may then be replaced with a low surface tension solvent such as methoxyno-naflurorbutane (C₄F₉OH₃).

The use of critical point drying effectively removes the first photoresist layer without causing undue damage to the underlying layer of graphene.

Critical point drying may be performed using a solvents and liquid CO2. In certain embodiments, the solvent comprises acetone and isopropyl alcohol (IPA).

In any embodiment, the at least one cavity may be a single cavity or an array of adjacent cavities.

In accordance with another aspect of the present invention, there is provided a method of manufacturing a graphene-based device, comprising:
providing a graphene assembly comprising one or more layers of graphene, and a first photoresist layer disposed on the one or more layers of graphene, transferring the graphene assembly onto a substrate comprising at least one cavity so that the one or more layers of graphene traverse the at least one cavity;
transferring the graphene assembly onto a substrate comprising at least one cavity so that the one or more layers of graphene traverse the at least one cavity;
using photolithography to expose portions of the graphene on opposite sides of the at least one cavity;
forming conductive contacts over the exposed portions of graphene; and removing the first photoresist layer;
wherein removing the first photoresist layer comprises using critical point drying.

The use of critical point drying effectively removes the first photoresist layer without causing undue damage to the underlying layer of graphene.

The step of providing the graphene assembly may comprise providing a precursor graphene assembly, wherein the precursor graphene assembly comprises the graphene assembly and a layer of copper disposed on a side of the one or more layers of graphene that is opposite to the first photoresist layer, and wherein the layer of copper is removed to provide the graphene assembly. For example, the precursor graphene assembly may be formed by chemical vapour deposition (CVD) of graphene on the layer of copper. CVD graphene is particularly suitable for use in the methods of the present invention. Wet etching may be used to remove the layer of copper.

The precursor graphene assembly may further comprise one or more sacrificial layers of graphene disposed on a side of the layer of copper that is opposite the one or more layers of graphene, and wherein the method further comprises removing the one or more sacrificial layers of graphene prior to removing the layer of copper. The sacrificial layer of graphene may arise from a CVD process whereby graphene is deposited on opposite sides of the layer of copper. Typically, the sacrificial layer of graphene will be of a lower quality than the layer of graphene to be used in the final device.

Plasma etching may be used to remove the one or more sacrificial layers of graphene.

The graphene may be substantially pure graphene (e.g. produced by CVD, exfoliation or otherwise), oxidized graphene (otherwise known as oxygenated graphene or graphene oxide), graphane (i.e. fluorinated graphene) and any other chemically functionalized graphene. The derivatives of graphene may be formed by modifying the layer of graphene 32 whilst it is on the precursor graphene assembly 32 or when it forms part of a final device, or indeed at any suitable stage in the intermediate fabrication process.

In certain embodiments, the substrate may comprise one or more of Si, SiO₂, SU8 polymer, sapphire or a semiconductor material. SU8 is a polymer that may advantageously be lithographically patterned to create cavities. SU8 is advantageously flexible, has high stability and is compatible with aqueous solutions.

The step of using photolithography to expose portions of the graphene on opposite sides of the at least one cavity may comprise disposing a second photoresist layer on the UV barrier layer, using a photomask to lithographically pattern the first photoresist layer so as to expose the portions of the one or more layers of graphene and leave remaining first photoresist layer traversing therebetween.

The step of forming conductive contacts may comprise depositing conductive material onto the exposed portions of graphene by thermal evaporation. The conductive material may comprise a layer of a first conductive material and a layer of a second conductive material. In certain embodiments, the first conductive material may comprise Cr and/or the second conductive material may comprise Au.

The method may further comprise using a further photoresist layer to mask the conductive material deposited on the exposed potions of graphene, removing any other deposited conductive material, and lithographically removing the further photoresist layer.

The step of removing any other deposited conductive material may be performed using wet etching.

The step of critical point drying to remove the first photoresist layer may be performed using a solvent and liquid CO₂. In certain embodiments, the solvent may comprise acetone and IPA.

In any embodiment, the at least one cavity may be a single cavity or an array of adjacent cavities.

In accordance with another aspect of the invention, there is provided a graphene-based device manufactured in accordance with any of the above-described methods.

In accordance with another aspect of the invention, there is provided a graphene-based device comprising:
a substrate comprising a plurality of cavities;
a plurality of layers of graphene, wherein each layer of graphene is disposed on the substrate and traverses at least one of the plurality of cavities; and
electrical contacts comprising conductive material disposed on the layers of graphene on opposite sides of each of the plurality of cavities.

In accordance with another aspect of the present invention, there is provided a gas sensor comprising a plurality of the graphene-based devices described above.

### BRIEF DESCRIPTION OF THE DRAWINGS

Embodiments of the invention are further described hereinafter with reference to the accompanying drawings, in which:

FIG. 1 illustrates a method according to an embodiment of the present invention;

FIG. 2 illustrates a method according to an alternative embodiment of the present invention;

FIG. 3 shows a schematic cross-sectional view of a precursor graphene assembly that may be used in a method according to embodiments of the present invention;

FIG. 4 shows a schematic cross-sectional view of the precursor graphene assembly of FIG. 3 after removal of a sacrificial layer of graphene;

FIG. 5 shows a schematic cross-sectional view of a graphene assembly that is formed by removing a layer of copper from the precursor graphene assembly of FIG. 4;

FIG. 6 shows a schematic cross-sectional view of a device comprising a substrate and the graphene assembly of FIG. 5;

FIG. 7 shows a schematic cross-sectional view of the device of FIG. 6 with a second photoresist layer disposed thereon;

FIG. 8 shows a schematic cross-sectional view of the device of FIG. 7 during a photolithography process;

FIG. 9 shows a schematic cross-sectional view of the device of FIG. 8 following the photolithography process shown in FIG. 8;

FIG. 10 shows a schematic cross-sectional view of the device of FIG. 9 following removal of exposed parts of the UV barrier layer;

FIG. 11 shows a schematic cross-sectional view of the device of FIG. 10 following removal of exposed parts of the first photoresist layer;

FIG. 12 shows a schematic cross-sectional view of the device of FIG. 11 following removal of exposed parts of the layer of graphene;

FIG. 13 shows a schematic cross-sectional view of the device of FIG. 12 with a third photoresist layer disposed thereon;

FIG. 14 shows a schematic cross-sectional view of the device of FIG. 13 during a photolithography process;

FIG. 15 shows a schematic cross-sectional view of the device of FIG. 14 following the photolithography process shown in FIG. 14;

FIG. 16 shows a schematic cross-sectional view of the device of FIG. 15 following removal of exposed parts of the UV barrier layer;

FIG. 17 shows a schematic cross-sectional view of the device of FIG. 16 following removal of exposed parts of the first photoresist layer;

FIG. 18 shows a schematic cross-sectional view of the device of FIG. 17 with a contact material disposed thereon;

FIG. 19 shows a schematic cross-sectional view of the device of FIG. 18 with a fourth photoresist layer disposed thereon;

FIG. 20 shows a schematic cross-sectional view of the device of FIG. 19 during a photolithography process;

FIG. 21 shows a schematic cross-sectional view of the device of FIG. 20 following the photolithography process;

FIG. 22 shows a schematic cross-sectional view of the device of FIG. 21 following removal of exposed parts of the contact material;

FIG. 23 shows a schematic cross-sectional view of the device of FIG. 22 following removal of exposed parts of the UV barrier layer;

FIG. 24 shows a schematic cross-sectional view of the device of FIG. 23 following removal of the remaining fourth photoresist layer and the remaining first photoresist layer;

FIG. 25 shows a top-down SEM image of an array of devices that each correspond to the embodiment shown in FIG. 24;

FIG. 26 shows a top-down SEM image of detail A of FIG. 25;

FIG. 27 shows a top-down SEM image of detail B of FIG. 26;

FIG. 28 shows a schematic cross-sectional view of a device according to an alternative embodiment of the present invention;

FIG. 29 shows a top-down SEM image of an array of devices that each correspond to the embodiment shown in FIG. 28;

FIG. 30 shows a top-down SEM image of detail C of FIG. 29;

FIG. 31 shows a top-down SEM image of detail D of FIG. 30;

FIG. 32 shows a schematic cross-sectional view of a device according to an alternative embodiment of the present invention;

FIG. 33 shows a graph representing the responses of a gas sensing device (with a sensor operating voltage of 1 V) that incorporates an array of graphene-based devices manufactured in accordance with embodiments of the present invention versus a known photoionization detector for successive gassing and degassing phases of toluene;

FIG. 34 shows a graph representing the responses of a gas sensing device (with a sensor operating voltage of 3 V) that incorporates an array of graphene-based devices manufactured in accordance with embodiments of the present invention versus a known photoionization detector for successive gassing and degassing phases of toluene; and

FIG. 35 shows a graph representing the response of a gas sensing device that incorporates an array of graphene-based devices manufactured in accordance with embodiments of the present invention during natural variations in pressure and temperature.

### DETAILED DESCRIPTION

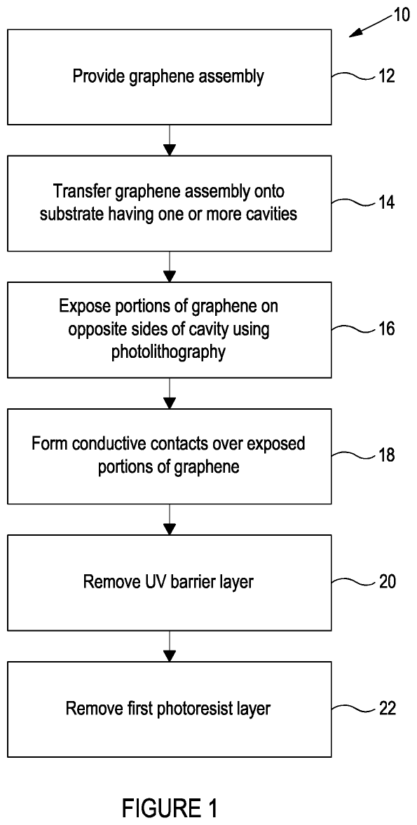

A method 10 of manufacturing a graphene-based device in accordance with an embodiment of the present invention is set out in FIG. 1. The method 10 comprises providing 12 a graphene assembly comprising one or more layers of graphene, a first photoresist layer disposed on the one or more layers of graphene, and an ultra-violet (UV) barrier layer disposed on the first photoresist layer on an opposite side to the one or more layers of graphene. The graphene assembly is transferred 14 onto a substrate comprising at least one cavity so that the one or more layers of graphene traverse the at least one cavity. Photolithography is used at step 16 to expose portions of the one or more layers of graphene on opposite sides of the at least one cavity and conductive contacts are formed at step 18 over the exposed portions of graphene. The UV barrier layer is then removed at step 20 and the first photoresist layer is removed at step 22.

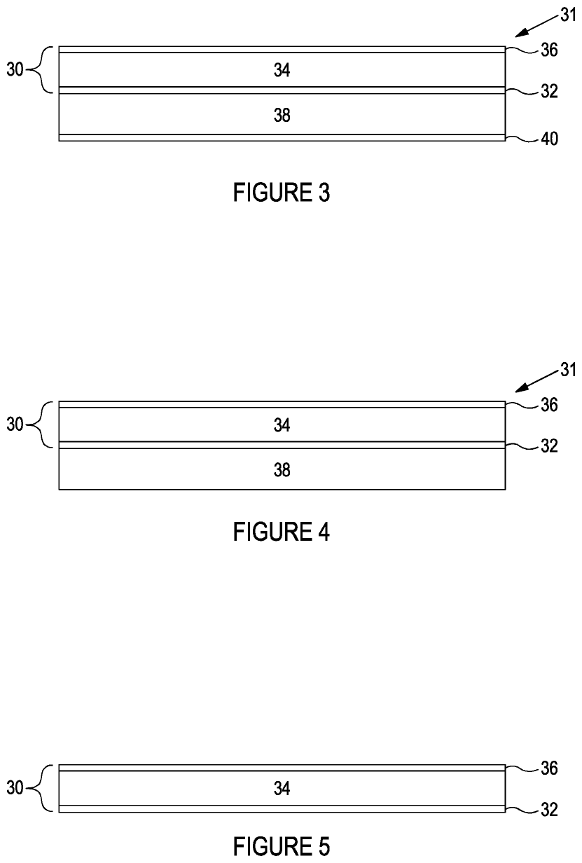

A specific method of manufacturing a graphene-based device according to an embodiment of the invention is described below with reference to FIGS. 3 to 23.

FIG. 3 shows a schematic cross-sectional view of a precursor graphene assembly 31 that may be used in a method according to embodiments of the present invention. The precursor graphene assembly 31 comprises a layer of copper 38 having a layer of graphene 32 on a first side and a sacrificial layer of graphene 40 on a second side that is opposite the first side. Throughout the present specification, any reference to a layer may be understood to mean one or more layers. For example, the layer of graphene 32 and/or the sacrificial layer of graphene 40 may each comprise a monolayer or a multilayer of graphene. The sacrificial layer of graphene 40 may be of a poorer quality than the layer of graphene 32. Throughout the present specification, the term graphene includes pure graphene and derivatives of graphene (e.g. modified graphene). In particular, the term graphene includes graphene (produced by CVD, exfoliation or otherwise), oxidized graphene (otherwise known as oxygenated graphene or graphene oxide), graphane (i.e. fluorinated graphene) and any other chemically functionalized graphene. The derivatives of graphene may be formed by modifying the layer of graphene 32 whilst it is on the precursor graphene assembly 32 or when it forms part of a final device, or indeed at any suitable stage in the intermediate fabrication process.

Disposed on the layer of graphene 32 is a first photoresist layer 34. The first photoresist layer 34 may, for example, be PR S1813, or any other suitable photoresist material. The first photoresist layer 34 may be spun coated on the layer of graphene 32 (e.g. to a thickness between 1 μm to 2 μm, or about 1.3 μm. The spin coated layer may then be baked to form the first photoresist layer 34 (e.g. at 85° C. for 30 minutes).

Disposed on the first photoresist layer 34 is a UV barrier layer 36. The UV barrier layer 36 may comprise any material and/or be of a thickness such that it is substantially impenetrable by UV radiation. In certain embodiments, the UV barrier layer 36 comprises one or more metals. The one or more metals may be vaporized and deposited on the first photoresist layer 34. In certain embodiments, the UV barrier layer comprises a layer of aluminium. In other embodiments, the UV barrier layer comprises a layer of gold, silver or chromium. In certain embodiments, the UV barrier 36 may have a thickness between 50 nm and 150 nm, and may be about 100 nm.

The combination of the layer of graphene 32, the first photoresist layer 34 and the UV barrier layer 36 forms a graphene assembly 30.

FIG. 4 shows the precursor graphene assembly 31 following the removal of the sacrificial layer of graphene 40. The sacrificial layer of graphene 40 may be removed by dry etching. For example, reactive-ion etching (or plasma etching) may be used. In one embodiment, O₂ plasma may be used to remove the sacrificial layer of graphene 40 (e.g. at 50 W under 100 mtorr of gas pressure for 3-5 minutes).

FIG. 5 shows the graphene assembly 30 following removal of the layer of copper 38 from the precursor graphene assembly 31. The layer of copper may be removed by any suitable method. In certain embodiments, an etchant may be used to remove the layer of copper 38. For example, the etchant may be ammonium persulphate. The precursor graphene assembly 31 may be floated on the surface of the etchant so that the layer of copper 38 is exposed to the etchant over a period of time (e.g. around 1 hour). Following exposure to the etchant, the graphene assembly 30 may be rinsed in deionized water one or more times to remove any residual copper and/or etchant. For example, the graphene assembly 30 may be rinsed in deionized water twice for a period of around 15 minutes each time.

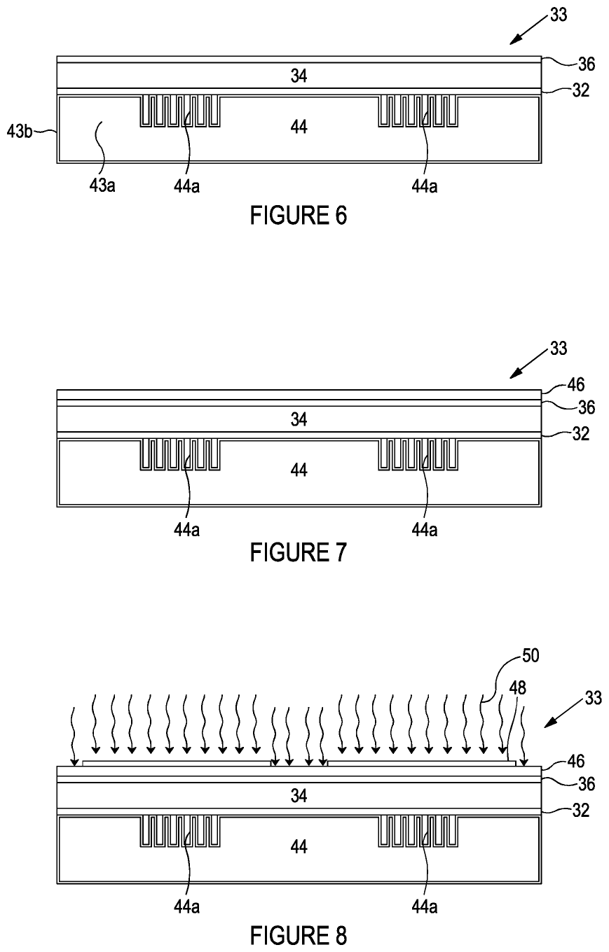

The graphene assembly 30 is floated in deionized water and transferred onto a substrate 44 to form a device 33 (albeit one that is not, at this stage, functional). In the embodiment shown in FIGS. 6 to 24, the substrate comprises a first substrate material 43a and a second substrate material 43b. In certain embodiments, the first substrate material 43a may comprise silicon (e.g. Si<100>, n+) and the second substrate material may comprise a layer of SiO₂ on the silicon. The substrate 44 comprises a plurality of cavities 44a. The cavities 44a may be formed in the first substrate material 43a (e.g. the silicon) before the second substrate material 43b is disposed on the first substrate material 43b. The second substrate material 43b may have a thickness of between 100 nm and 500 nm, and optionally around 300 nm. Each cavity is separated from an adjacent cavity by a wall defined by the substrate 44. The wall may be several pm thick (e.g. 1-3 μm, or about 2 μm). The length of each cavity is determined by the length of the wall. In certain embodiments, the length of each cavity may be several μm (e.g. 4-8 μm, or about 6 μm). The cavities may be square, rectangular, or otherwise formed. The cavities 44a may be arranged in groups so that one series of cavities 44a is separated, periodically, from an adjacent series of cavities 44a. In certain embodiments, the spacing between adjacent groups of cavities 44a may be between 100 μm and 400 μm, and optionally around 250 μm.

The graphene assembly is transferred onto the substrate 44 such that the layer of graphene 32 traverses the cavities 44a. By traversing, the layer of graphene 32 extends from one side of a given cavity 44a to an opposite side of the cavity 44a such that the layer of graphene is supported at either side and has at least a portion that is suspended above the cavity 44a. In certain embodiments, each of the cavities may have a depth (i.e. extending downwards into the substrate 44) of between 500 nm and 1500 nm, and optionally about 1000 nm. The cavities may form an array of cavities 44a that cover an area on the substrate of several μm². For example, in certain embodiments, the area on the substrate 44 covered by a single group of cavities 44a may be between 80 μm² and 150 μm²,. In one particular example, the area covered by a single group of cavities 44a may be about 100 μm×120 μm.

The substrate 44 may comprise any suitable material that can support the existence of cavities over which a layer of graphene 32 may be suspended (and supported on either side of each cavity). In certain embodiments, the substrate 44 comprises one or more polymers. In certain embodiments, the substrate 44 may comprise one or more of Si, SiO₂, or SU8 polymer. The choice of material(s) for the substrate 44 may be determined by the required qualities of the final device to be produced.

Following transfer of the graphene assembly 30 onto the substrate 44, a second photoresist layer 46 is disposed on the graphene assembly 30, in particular on the UV barrier layer 36. The second photoresist layer 46 may be any suitable photoresist material. In certain embodiments, the second photoresist layer 46 may comprise PR S1805. The second photoresist layer 46 may be spin coated on the UV barrier layer 36 (e.g. at around 4000 rpm for about 30 seconds). The spin coated layer may have a thickness between 0.3 μm and 0.7 μm, or about 0.5 μm. The spin coated layer may then be baked to form the second photoresist layer 46 (e.g. at 115° C. for 1 minute). FIG. 7 shows the graphene assembly 30 with the second photoresist layer 46 disposed on the UV barrier layer 36.

With the second photoresist layer 46 in place, a first photomask 48 is positioned so as to cover parts of the second photoresist layer 46 that lie over (i.e. traverse) the plurality of cavities 44a. The device 33 is then exposed to UV radiation 50, where the first photomask 48 prevents the UV radiation 50 from reaching the covered parts of the second photoresist layer 46. That is, only parts of the second photoresist layer 46 that are not covered by the first photomask 48 are subjected to UV radiation 50. FIG. 8 shows the device 33 of FIG. 7 during this photolithography process. In certain embodiments, the UV radiation 50 may have a wavelength (or wavelengths) between 350 nm and 400 nm and/or may have a power around 1 W/cm². The second photoresist layer 46 may be exposed to the UV radiation 50 for a period that may be dependent on the thickness of the second photoresist layer 46 and the type of material used for the second photoresist layer 46. Typically, a specification sheet associated with a particular photoresist material may be used to determine an appropriate time period. In one example, this period is between 15 s and 25 s, and optionally between 18 s and 20 s.

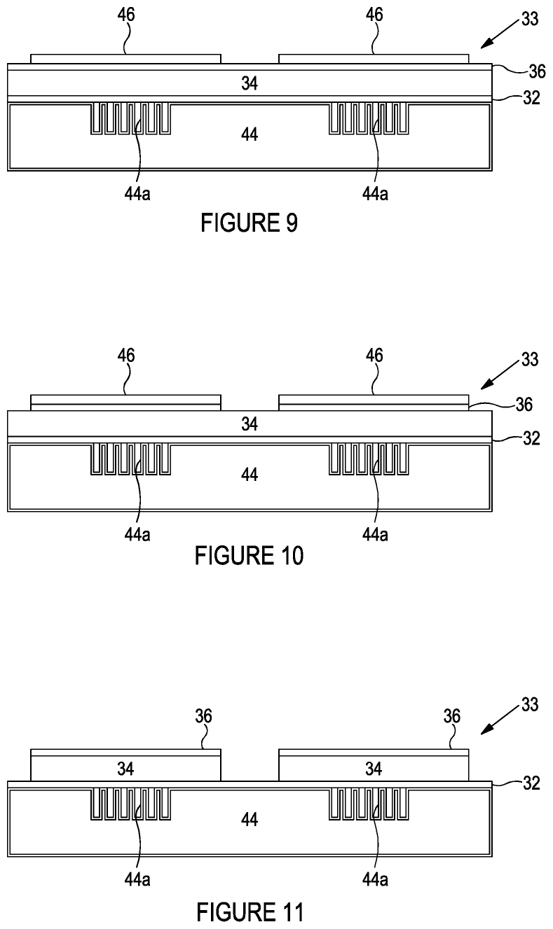

Parts of the second photoresist layer 46 that are subjected to the UV radiation 50 may be removed by a subsequent process step, leaving the non-exposed parts in place. The device 33 may undergo a post-baking step (e.g. at around 110° C.) following exposure to the UV radiation 50 but before removal of the exposed parts of the second photoresist layer 46. In certain embodiments, the exposed parts of the second photoresist layer 46 may be removed by a 1:1 ratio of MicroDev developer solution and deionized water. MicroDev developer solution is found to effectively remove the second photoresist layer 46 without inadvertently removing the UV barrier layer 36 (e.g. if it is aluminium). The device 33 may then be rinsed (e.g. in deoinised water) to remove any remaining second photoresist layer 46 intended for removal, and any developing agent, and subsequently dried (e.g. in nitrogen gas). FIG. 9 shows the device 33 following the removal of the exposed parts of the second photoresist layer 46.

The removal of parts of the second photoresist layer 46 exposes parts of the underlying UV barrier layer 36, as shown in FIG. 9. These exposed parts of the UV barrier layer 36 may subsequently be removed. For example, the exposed parts of the UV barrier layer 36 may be removed by wet etching. In particular, the device 33 may be floated on an etchant such that the exposed UV barrier layer is face-down in the etchant. This process may be performed over several minutes (e.g. 4-6 min, or about 5 min) until the exposed UV barrier layer 36 has been removed. In certain embodiments, a suitable etchant may be phosphoric nitric acetic acid (this is particularly suitable in embodiments where the UV barrier layer 36 comprises aluminium). Following exposure to the etchant, the device 33 may be rinsed (e.g. in deionized water) and dried (e.g. in nitrogen gas) to remove any remaining UV barrier layer (that is intended for removal) and/or etchant. FIG. 10 shows the device 33 following the removal of the exposed parts of the UV barrier layer 36.

The removal of parts of the UV barrier layer 36 exposes parts of the first photoresist layer 34, as shown in FIG. 10. These exposed parts of the first photoresist layer 34 may be removed using a photolithography process similar to the one described above with reference to FIG. 8. Simultaneously, the remaining second photoresist layer 46 may be subjected to UV radiation, and both the second photoresist layer 46 and the exposed parts of the first photoresist layer 34 may be removed in a subsequent developing step (described below). In certain embodiments, the UV radiation may have a frequency (or frequencies) between 350 nm and 400 nm and/or may have a power around 1 W/cm². The second photoresist layer 46 and exposed parts of the first photoresist layer 34 may be exposed to the UV radiation for a period between 65 s and 70 s. In certain embodiments, the second photoresist layer 46 and the exposed parts of the first photoresist layer 34 may be removed by a 1:1 ratio of MicroDev and deionized water. The device 33 may then be rinsed (e.g. in deoinised water) to remove any remaining second photoresist layer 46 intended for removal, and any developing agent, and subsequently dried (e.g. in nitrogen gas). FIG. 11 shows the device 33 following the removal of the second photoresist layer 46 and the exposed parts of the first photoresist layer 34.

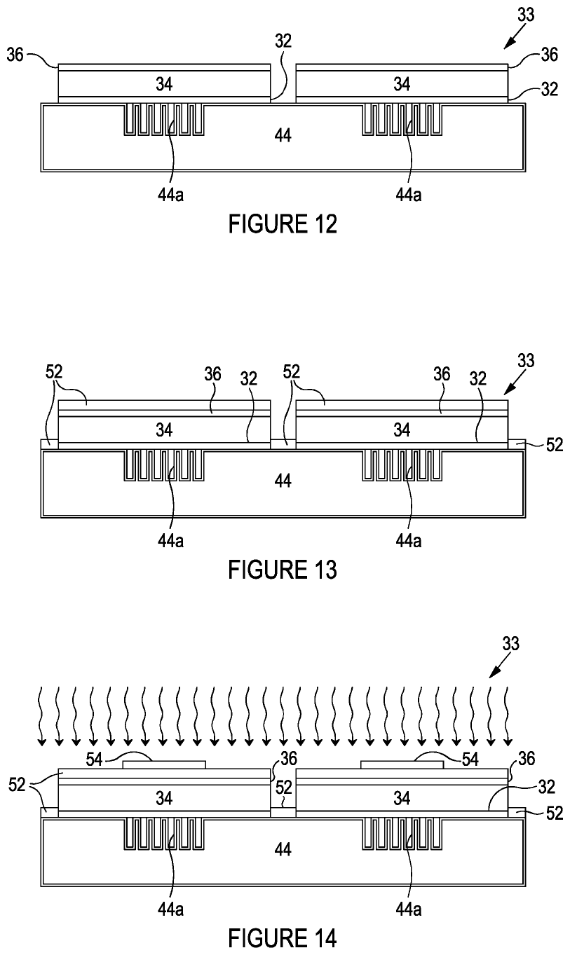

The removal of the exposed parts of the first photoresist layer 34 exposes parts of the layer of graphene 32 below, as shown in FIG. 11. These exposed parts of the layer of graphene 32 are then removed. Removal of the exposed parts of the layer of graphene 32 may be achieved by dry etching. For example, the method of dry etching employed may be reactive-ion etching (RIE) (or plasma etching). In particular, the exposed parts of the layer of graphene 32 may be exposed to an O₂ plasma (e.g. at 50 W, under 100 mtorr oxygen gas pressure for 3-5 mintues to cause their removal. FIG. 12 shows the device 33 with the previously-exposed parts of the layer of graphene 32 removed.

A third photoresist layer 52 is then disposed on the device 33, in particular on the UV barrier layer 36 (which is once again exposed at this stage) and on the substrate 44 at the sites from where the previously-exposed parts of the layer of graphene 32 were removed. The third photoresist layer 52 may be any suitable photoresist material. In certain embodiments, the third photoresist layer 52 may comprise PR S1805. The third photoresist layer 52 may be spin coated on the UV barrier layer 36 (e.g. at around 4000 rpm for about 30 seconds). The spin coated layer may have a thickness between 0.3 μm and 0.7 μm, or about 0.5 pm. The spin coated layer may then be baked to form the third photoresist layer 52 (e.g. at 115° C. for 1 minute). FIG. 13 shows the graphene assembly 30 with the third photoresist layer 52 disposed on the UV barrier layer 36.

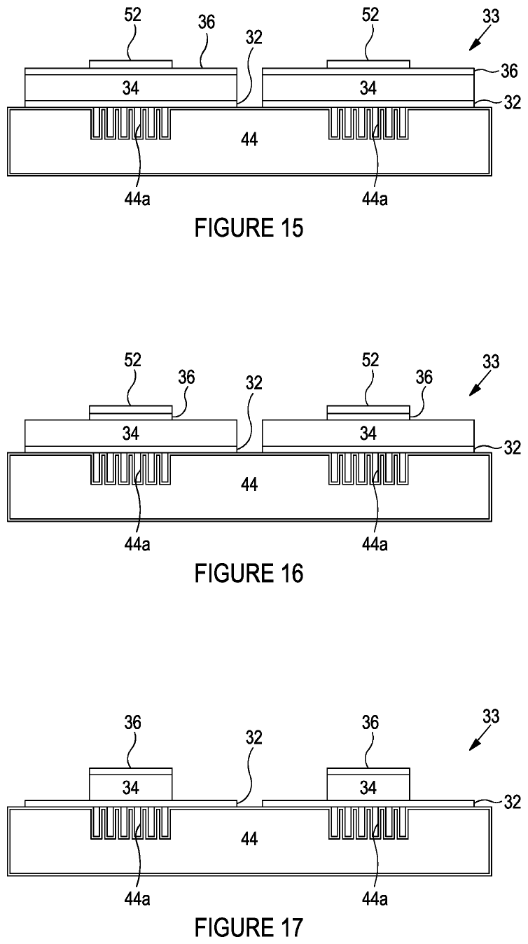

A second photomask 54 is then used to cover parts of the third photoresist layer 52 that are disposed vertically above the plurality of cavities 44a. The remaining (i.e. uncovered) third photoresist layer 52 is then exposed to UV radiation 50 in a photolithography process shown in FIG. 14. In certain embodiments, the UV radiation may have a frequency (or frequencies) between 350 nm and 400 nm and/or may have a power around 1 W/cm². The third photoresist layer 52 may be exposed to the UV radiation for a period between 15 s and 25 s, and optionally between 18 s and 20 s. In certain embodiments, the third photoresist layer 52 may be removed by a 1:1 ratio of MicroDev and deionized water. The device 33 may then be rinsed (e.g. in deoinised water) to remove any remaining third photoresist layer 52 intended for removal, and any developing agent, and subsequently dried (e.g. in nitrogen gas). FIG. 15 shows the device 33 following the removal of parts of the third photoresist layer 52.

The removal of parts of the third photoresist layer 52 exposes parts of the underlying UV barrier layer 36, as shown in FIG. 15. These exposed parts of the UV barrier layer 36 may subsequently be removed. For example, the exposed parts of the UV barrier layer 36 may be removed by wet etching. In particular, the device 33 may be floated on an etchant such that the exposed UV barrier layer is face-down in the etchant. This process may be performed over several minutes (e.g. 4-6 min, or about 5 min) until the exposed UV barrier layer 36 has been removed. In certain embodiments, a suitable etchant may be phosphoric nitric acetic acid (this is particularly suitable in embodiments where the UV barrier layer 36 comprises aluminium). Following exposure to the etchant, the device 33 may be rinsed (e.g. in deionized water) and dried (e.g. in nitrogen gas) to remove any remaining UV barrier layer (that is intended for removal) and/or etchant. FIG. 16 shows the device 33 following the removal of the exposed parts of the UV barrier layer 36.

The removal of parts of the UV barrier layer 36 exposes new parts of the first photoresist layer 34, as shown in FIG. 16. These exposed parts of the first photoresist layer 34 may be removed using a photolithography process similar to the one described above with reference to FIG. 8. Simultaneously, the remaining third photoresist layer 52 may be subjected to UV radiation, and both the third photoresist layer 52 and the exposed parts of the first photoresist layer 34 may be removed in a subsequent developing step (described below). In certain embodiments, the UV radiation may have a frequency (or frequencies) between 350 nm and 400 nm and/or may have a power around 1 W/cm². The third photoresist layer 52 and exposed parts of the first photoresist layer 34 may be exposed to the UV radiation for a period between 65 s and 70 s. In certain embodiments, the third photoresist layer 52 and the exposed parts of the first photoresist layer 34 may be removed by a 1:1 ratio of MicroDev and deionized water. The device 33 may then be rinsed (e.g. in deoinised water) to remove any remaining third photoresist layer 52 intended for removal, and any developing agent, and subsequently dried (e.g. in nitrogen gas). The steps of developing and rinsing may additionally clean the newly exposed parts of the layer of graphene 32 beneath. FIG. 17 shows the device 33 following the removal of the third photoresist layer 52 and the exposed parts of the first photoresist layer 34.

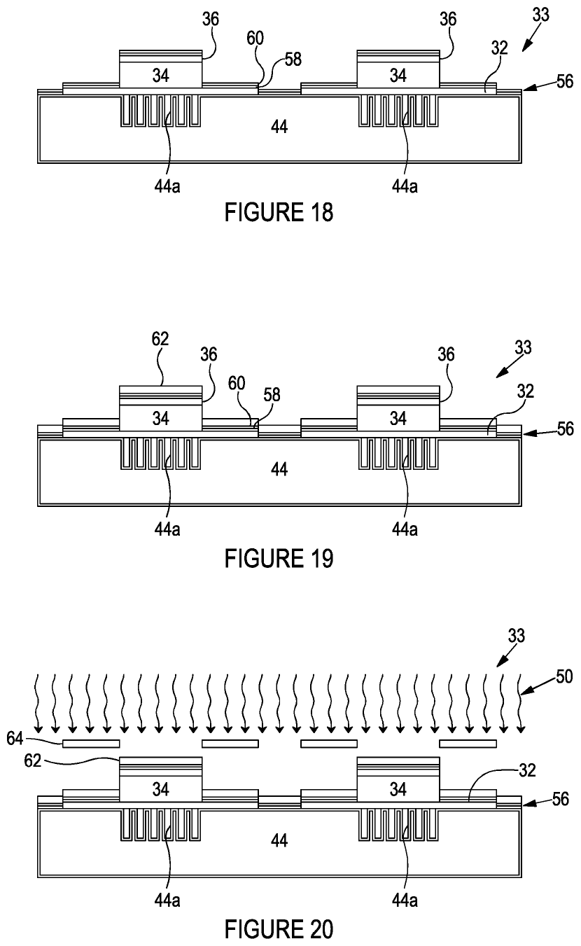

The process described above in relation to FIGS. 3 to 17 represents certain embodiments that are in accordance with steps 12, 14 and 16 of the method 10 set out in FIG. 1. The process described below in relation to FIG. 18 represents an embodiment that is in accordance with step 18 of the method 10 of FIG. 1. In particular, conductive contacts are formed over the exposed portions of the layer of graphene 32. With reference to FIG. 18, the conductive contacts are formed by first disposing a conductive material 56 on the device 33 and subsequently removing unwanted parts of the conductive material 56 (which is described below). The conductive material 56 may be deposited by any suitable method. For example, the conductive material 56 may be deposited by vapour deposition (i.e. thermal evaporation). Vapour deposition may be performed at low pressure (e.g. around 2×10⁻⁶ torr).

In the non-limiting embodiment shown in the Figures, the conductive material 56 comprises a layer of a first conductive material 58 and a layer of a second conductive material 60 disposed on top of the layer of a first conductive material 58 (in other embodiments, the conductive material 56 may comprise a single layer of a single conductive material or multiple (i.e. two or more) layers of different conductive materials. Either or both of the layer of a first conductive material 58 and a layer of a second conductive material 60 may be deposited by vapour deposition (e.g. in a sequential process). In certain embodiments, the layer of a first conductive material 58 may comprise chromium and/or the layer of a second conductive material 60 may comprise gold. In certain embodiments, the layer of a first conductive material 58 (whether it is chromium or another conductive material) may have a thickness between 8 and 12 nm, and optionally 10 nm. Additionally or alternatively, the layer of a second conductive material 60 (whether it is gold or another conductive material) may have a thickness between 150 nm and 250 nm, and optionally 200 nm.

Once the conductive material 56 has been deposited on the device 33, a fourth photoresist layer 62 is then disposed on the device 33, in particular on conductive material 56. The fourth photoresist layer 62 may be any suitable photoresist material. In certain embodiments, the fourth photoresist layer 62 may comprise PR S1805. The fourth photoresist layer 62 may be spin coated on the conductive material 56 (e.g. at around 4000 rpm for about 30 seconds). The spin coated layer may have a thickness between 0.3 μm and 0.7 μm, or about 0.5 μm. The spin coated layer may then be baked to form the fourth photoresist layer 62 (e.g. at 115° C. for 1 minute). FIG. 19 shows the device 33 with the fourth photoresist layer 62 disposed on the conductive material 56.

A third photomask 64 is then used to cover parts of the fourth photoresist layer 62 that are disposed either side of the plurality of cavities 44a (i.e. leaving parts of the fourth photoresist layer 62 that are disposed vertically above the plurality of cavities 44a exposed). Additionally, gaps in the third photomask 64 leave portions of the fourth photoresist layer 62 between adjacent ones of the plurality of cavities 44a exposed.

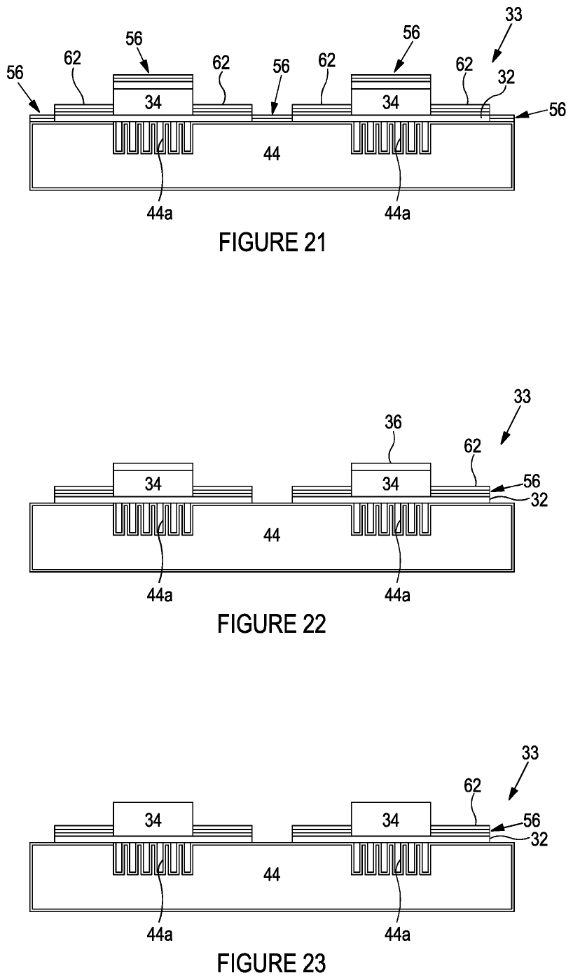

The uncovered portions of the fourth photoresist layer 62 is then exposed to UV radiation 50 in a photolithography process shown in FIG. 20. In certain embodiments, the UV radiation 50 may have a frequency (or frequencies) between 350 nm and 400 nm and/or may have a power around 1 W/cm². The fourth photoresist layer 62 may be exposed to the UV radiation 50 for a period between 15 s and 25 s, and optionally between 18 s and 20 s. In certain embodiments, the fourth photoresist layer 62 may be removed by a 1:1 ratio of MicroDev and deionized water. The device 33 may then be rinsed (e.g. in deoinised water) to remove any remaining fourth photoresist layer 62 intended for removal, and any developing agent, and subsequently dried (e.g. in nitrogen gas). FIG. 21 shows the device 33 following the removal of parts of the fourth photoresist layer 62. As a result, the remaining fourth photoresist layer 62 covers only the conductive material 56 that is to be retained as the conductive contacts of the device 33. The remaining conductive material (which is no longer covered by the fourth photoresist layer 62 and is therefore exposed) is removed by wet etching. In particular, the device 33 may be floated on an etchant such that the exposed conductive material 56 is face-down in the etchant. This process may be performed over several minutes (e.g. 4-6 min, or about 5 min) until the exposed conductive material 56 has been removed. The wet etching may be performed in two stages with a first stage for removing the layer of second conductive material 60 and a second stage for removing the layer of first conductive material 58. In certain embodiments, a suitable etchant may be selected for each of the first conductive material 58 and the second conductive material 60, where the etchants may be different to one another. In one example, a suitable etchant for removing chromium may be Ceric ammonium nitrate (e.g. from Sigma-Aldrich Corporation). A suitable etchant for removing gold may be KI:I₂:H₂O=4 g:1 g: 40 ml. Following exposure to the etchant, the device 33 may be rinsed (e.g. in deionized water) and dried (e.g. in nitrogen gas) to remove any conductive material 56 (that is intended for removal) and/or etchant. FIG. 22 shows the device 33 following the removal of the exposed parts of the conductive material 56.

Removal of the exposed parts of the conductive material 56 exposes the UV barrier layer 36 once more. In a subsequent step (corresponding to step 20 of method 10), the UV barrier layer 36 is removed. For example, the UV barrier layer 36 may be removed by wet etching. In particular, the device 33 may be floated on an etchant such that the UV barrier layer 36 is face-down in the etchant. This process may be performed over several minutes (e.g. 4-6 min, or about 5 min) until the UV barrier layer 36 has been removed. In certain embodiments, a suitable etchant may be phosphoric nitric acetic acid (this is particularly suitable in embodiments where the UV barrier layer 36 comprises aluminium). Following exposure to the etchant, the device 33 may be rinsed (e.g. in deionized water) and dried (e.g. in nitrogen gas) to remove any remaining UV barrier layer and/or etchant. FIG. 23 shows the device 33 following the removal of the UV barrier layer 36.

In accordance with the final step 22 of the method 10, the first photoresist layer 34 is removed. Crucially, the step 22 of removing the first photoresist layer should not damage the underlying layer of graphene 32 to the point where it can no longer function as intended in the final device 33. In one advantageous aspect of the present invention, the step 22 of removing the first photoresist layer 34 is performed by employing critical point drying (CPD). In such cases, a solvent may be used to remove the first photoresist layer 34. In certain embodiments, the solvent may be one that is miscible in liquid CO₂. In certain embodiments, the solvent may be acetone. In alternative embodiments, the solvent may comprise ethanol or a suitable resist remover. During this process, the device is maintained in a protective wet state that reduces the risk of damage to the layer of graphene 32. The device 33 is immersed vertically in the solvent (e.g. for around an hour) to remove the first photoresist layer 34. Next, the solvent is slowly replaced with isopropyl alcohol (IPA) in a CPD chamber. The IPA serves to remove any residue of the solvent. This step may be performed over a time period of several minutes (e.g. around 2 minutes). Once the solvent has been replaced with the IPA, the IPA is replaced with liquid CO₂ in a CPD chamber. This may be performed over several minutes (e.g. 2 minutes) until all the IPA is replaced with liquid CO₂. The liquid CO₂ is then removed by increasing the CPD chamber to the critical point of CO₂ (approximately 32° C. at 1150 PSI) to cause the liquid CO₂ to convert into a gas. Once the first photoresist layer 32 has been removed and the solvent and CO₂ removed, the device is annealed (e.g. at 280° C. under N2 environment) after which device 33 is finalized and is capable of functioning.

The UV barrier layer provides a desirable UV shielding effect, thereby serving to protect the underlying layer of graphene from UV radiation (employed as part of photolithography operations) during fabrication of the device. The presence and removal of the UV barrier layer does not unduly affect the properties (e.g. mechanical/electronic) of the layer of graphene during fabrication. Such protection affords a higher yield of successfully fabricated areas of suspended graphene (i.e. graphene that traverses at least one cavity) on a substrate, and therefore lends itself to the production of a functional device that includes a large array of suspended layers of graphene.

In embodiments where the UV barrier layer comprises a metal (such as aluminium, in particular), the metal UV barrier layer not only provides the desired UV protection, but it also serves to provide additional mechanical strength and mechanical shielding to the layer of graphene (and possibly other parts of the device) during fabrication.

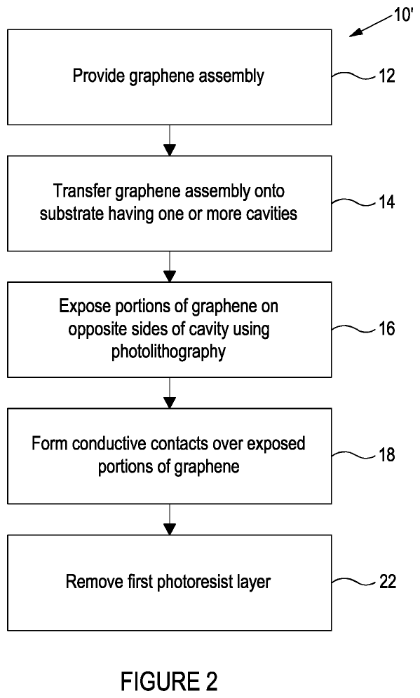

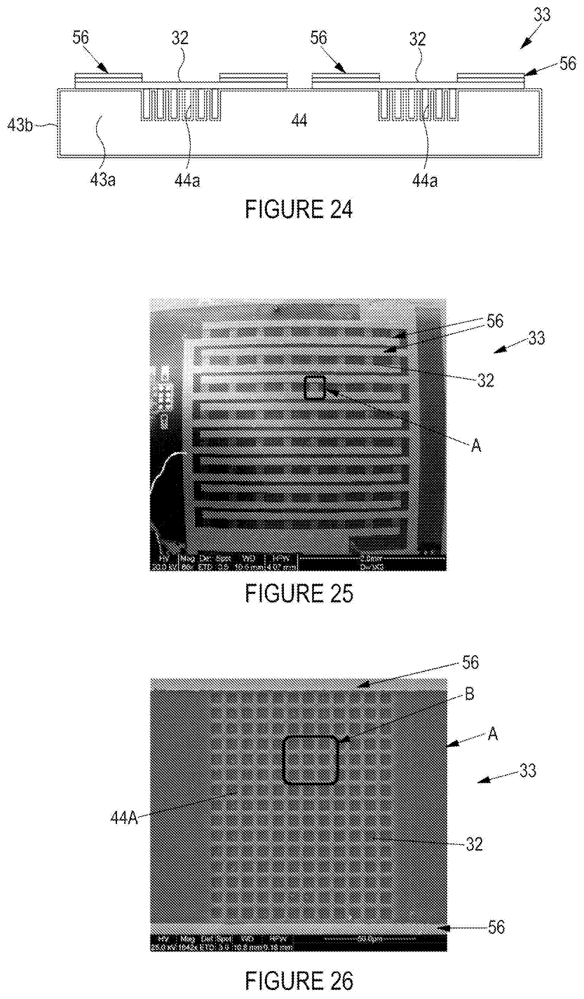

A method 10′ according to an alternative aspect of the invention is set out in FIG. 2. The method 10′ of FIG. 2 is identical to the method 10 of FIG. 1 save for the fact that the graphene assembly provided in step 12 does not include a UV barrier layer, and so the method 10′ does not include a step of removing the UV barrier layer. Considering the method described above with reference to FIGS. 6 to 24, if there were no UV barrier layer present (in accordance with the method 10′ of FIG. 2), then the steps described above with reference to FIGS. 7 to 10 would not be required. Instead, a photomask (used as part of a lithography process) could be used to pattern the first photoresist layer 34 to arrive at the device 33 shown in FIG. 11 (albeit with no UV barrier layer 36). A further photomask (used as part of a further lithography process) could be used to arrive at the device 33 shown in FIG. 17 (albeit with no UV barrier layer 36). The steps described above with reference to FIGS. 18 to 21 could then be performed to arrive at the device 33 shown in FIG. 23. In accordance with the method 10′ of FIG. 2, the step 22 of removing the first photoresist layer 34 necessarily comprises employing critical point drying (unlike the method 10 of FIG. 1 in which step 22 may comprise employing CPD or any other suitable alternative method of removing the first photoresist layer without rendering the underlying graphene non-functional). Therefore, in accordance with the method 10′ of FIG. 2, CPD is used to arrive at the device 33 of FIG. 24 from the device 33 of FIG. 23. The use of CPD effectively removes the first photoresist layer 34 without causing undue damage to the underlying layer of graphene.

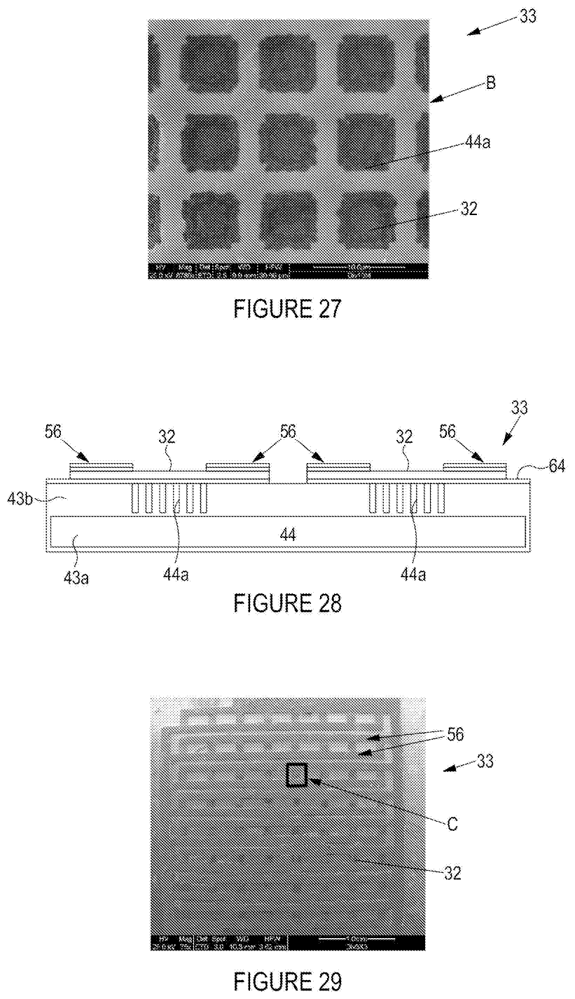

FIG. 25 shows a top-down SEM image of an array of devices 33 that each correspond to the embodiment shown in FIG. 24. The array covers a total area of 3 mm×3 mm. From FIG. 25, it can be seen how the conductive material 56 forms contacts that are arranged in pairs. Each half of the pairs are joined along a common electrical path. Between each contact of a given pair, the layer of graphene 32 extends. In the SEM image of FIG. 25, the underlying cavities 44a can be seen. In particular, the cavities 44a can be more clearly seen in FIGS. 26 and 27 which show top-down SEM images of detail A of FIG. 25 and detail B of FIG. 26, respectively.

FIG. 28 shows a schematic cross-sectional view of a device 33 according to an alternative embodiment of the present invention (components corresponding to those described above are identified with like reference numerals). A notable difference between the device 33 of FIG. 28 and the above-described devices is that the cavities 44a are formed only in the second substrate material 43b and not the first substrate material 43a. Indeed, the first substrate material 43a merely provides a support for the second substrate material 43b. In certain embodiments, the second substrate material 43b may comprise SiO₂. The first substrate material 43a may comprise silicon, or indeed any other suitable substrate (e.g. a semiconducting material, or a non-conducting materials such as glass, a hardened polymer, and/or a flexible plastic such as PDMS or polyamide).

Additionally, the non-limiting embodiment shown in FIG. 28 comprises a layer of chromium 64 (of approximately 50 nm) between the layer of graphene 32 and the substrate 44. The layer of chromium 64 may prevent the layer of graphene 32 becoming contaminated due to contact with the substrate 44. In particular, the second substrate material 43b (particularly if it comprises SiO₂) may have charged functional groups (or other contaminants) on its surface and these may adversely affect the layer of graphene 32 if they come into contact with the layer of graphene 32. In alternative embodiments, the layer of chromium 64 may be substituted with other suitable materials that may prevent contamination of the layer of graphene 32 from contact with the substrate 44. In alternative embodiments, the device 32 of FIG. 27 may not include the layer of chromium 64 (or any similar layer) but be otherwise identical to that shown and described above.

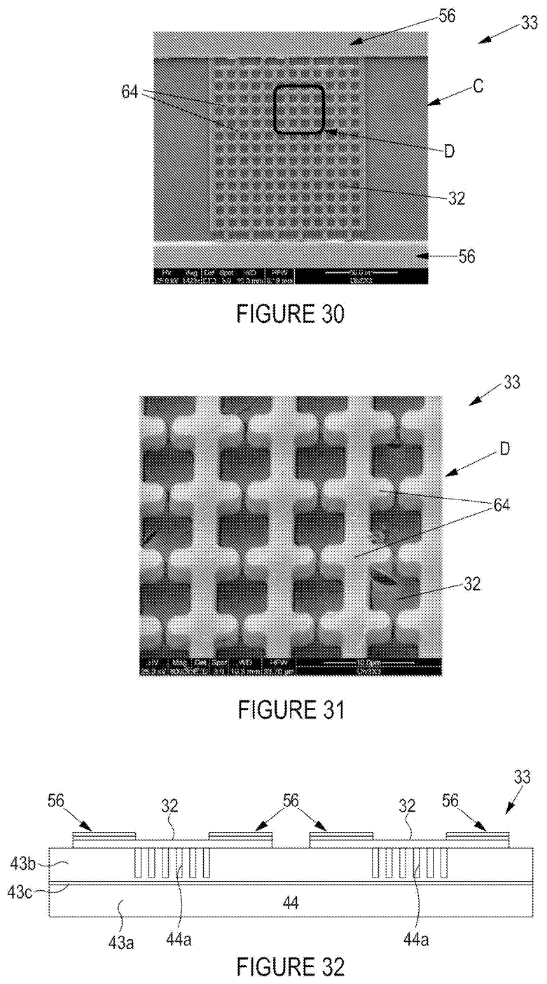

FIG. 29 shows a top-down SEM image of an array of devices that each correspond to the embodiment shown in FIG. 27. The array covers a total area of 3 mm×3 mm. From FIG. 29, it can be seen how the conductive material 56 forms contacts that are arranged in pairs. Each half of the pairs are joined along a common electrical path. Between each contact of a given pair, the layer of graphene 32 extends. In the SEM image of FIG. 29, the underlying cavities 44a can be seen. In particular, the cavities 44a can be more clearly seen in FIGS. 30 and 31 which show top-down SEM images of detail C of FIG. 29 and detail D of FIG. 30, respectively. Additionally, the underlying layer of chromium 64 can also be seen in FIGS. 29 to 31 extending over the cavities 44a.

FIG. 32 shows a schematic cross-sectional view of a device 33 according to a further alternative embodiment of the present invention (components corresponding to those described above are identified with like reference numerals). Like the device 33 of FIG. 28, the cavities 44a are formed exclusively in the second substrate material 43b. No additional layer of chromium is provided between the layer of graphene 32 and the substrate 44. In the embodiment of FIG. 32, the second substrate material 43b may comprise 1.3-micron spin coated and hard backed SU8 polymer or sputter coated 1.3 micron SiO₂. The first substrate material 43a may comprise silicon, or indeed any other suitable substrate (e.g. a semiconducting material, or a non-conducting materials such as glass, a hardened polymer, and/or a flexible plastic such as PDMS or polyamide). An intermediate third substrate material 43c may be provided between the first substrate material 43a and the second substrate material 43b. The third substrate material 43c may be a thin layer (e.g. about 100 nm). In certain embodiments, the third substrate material 43c may comprise aluminium. In alternative embodiments, the third substrate material 43c may comprise other suitable materials, e.g. other metals.

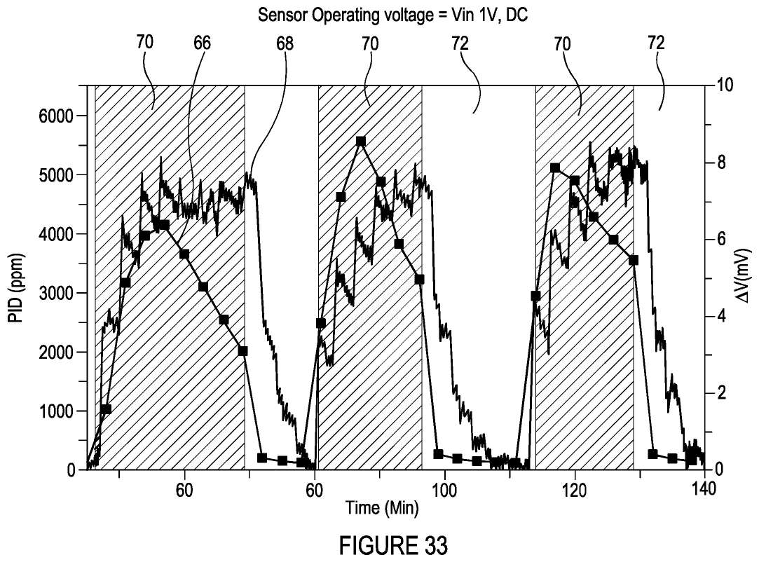

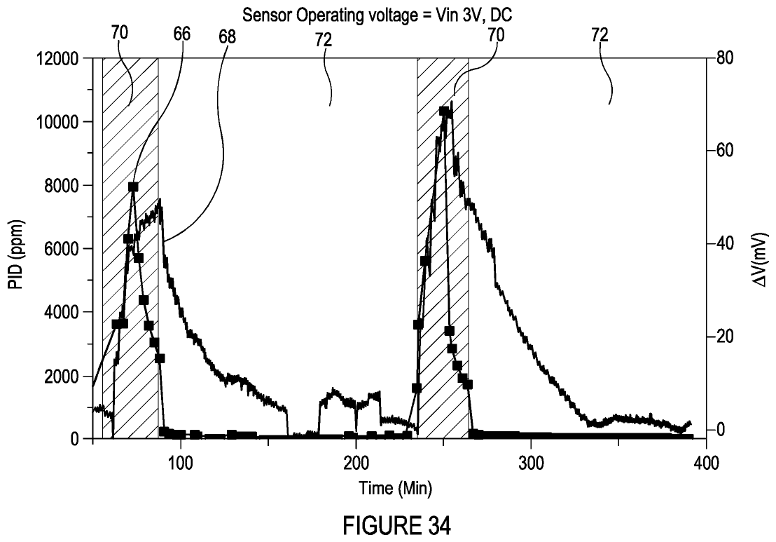

FIG. 33 shows a graph representing the responses of a gas sensing device that incorporates an array of graphene-based devices manufactured in accordance with embodiments of the present invention versus a known photoionisation detector for successive gassing and degassing phases of toluene. In particular, the graph shows that in successive gassing phases 70 and degassing phases 72, the graphene-based device (indicated by line 68) has an immediate response time (comparable to the PID which is indicated by line 66) and has a sensitivity of 6 ppm. These results demonstrate that a functional graphene-based device may be produced using the above-described methods in accordance with embodiments of the present invention. Moreover, the produced device may be comparable in performance to existing PIDs. The sensor operating voltage (Vᵢₙ) of the graphene-based devices of FIG. 33 is 1 V. FIG. 34 shows an equivalent comparative graph, where Vᵢₙ=3 V.

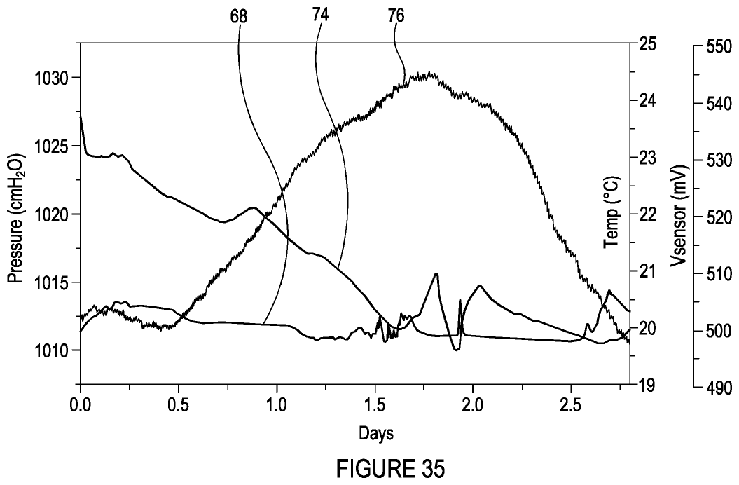

FIG. 35 shows a graph representing the response of a gas sensing device that incorporates an array of graphene-based devices manufactured in accordance with embodiments of the present invention during natural variations in pressure and temperature. In particular, line 68 shows the response of the graphene-based sensing device as the temperature (line 74) and the pressure (line 76) vary naturally over a time period of several days. The results show that the behavior of the graphene-based device is not significantly affected by such natural variations. In particular, this suggests that if there was air trapped within the cavities 44a during fabrication, such air does not adversely affect the performance of the final device in response to natural variations in temperature or pressure (e.g. by expanding/contracting and inducing strain on the layer of graphene).

Devices according to certain embodiments of the present invention may therefore utilize suspended graphene membranes to provide real-time, ultrasensitive VOC detection. The graphene membranes can be functionalized on the top surface allowing for detection selectivity. The devices may be CMOS compatible, meaning that production of the devices can be scaled up on known semiconductor fabrication lines. Sensors incorporating devices in accordance with embodiments of the present invention may require low voltages to operate, may offer immediate response times, high sensitivity and/or a larger theoretical range of detection. Furthermore, such devices may be considerably cheaper and/or more portable than prior art devices.

Throughout the description and claims of this specification, the words “comprise” and “contain” and variations of them mean “including but not limited to”, and they are not intended to (and do not) exclude other moieties, additives, components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds, chemical moieties or groups described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

The reader's attention is directed to all papers and documents which are filed concurrently with or previous to this specification in connection with this application and which are open to public inspection with this specification, and the contents of all such papers and documents are incorporated herein by reference.

1. A method of manufacturing a graphene-based device, comprising:
providing a graphene assembly comprising one or more layers of graphene, a first photoresist layer disposed on the one or more layers of graphene, and an ultra-violet (UV) barrier layer disposed on the first photoresist layer on an opposite side to the one or more layers of graphene;
transferring the graphene assembly onto a substrate comprising at least one cavity so that the one or more layers of graphene traverse the at least one cavity;
using photolithography to expose portions of the one or more layers of graphene on opposite sides of the at least one cavity;
forming conductive contacts over the exposed portions of graphene;
removing the UV barrier layer; and
removing the first photoresist layer.

2. The method of claim 1, wherein the UV barrier layer comprises aluminium, gold, silver or chromium.

3. The method of claim 1, wherein providing the graphene assembly comprises providing a precursor graphene assembly, wherein the precursor graphene assembly comprises the graphene assembly and a layer of copper disposed on a side of the one or more layers of graphene that is opposite to the first photoresist layer, and wherein the layer of copper is removed to provide the graphene assembly.

4. (canceled)

5. The method of claim 3, wherein the precursor graphene assembly further comprises one or more sacrificial layers of graphene disposed on a side of the layer of copper that is opposite the one or more layers of graphene, and wherein the method further comprises removing the one or more sacrificial layers of graphene prior to removing the layer of copper.

6. (canceled)

7. The method of any preceding claim 1, wherein the substrate comprises of Si, SiO₂, or SU8 polymer.

8. The method of any preceding claim 1, wherein using photolithography to expose portions of the graphene on opposite sides of the at least one cavity comprises disposing a second photoresist layer on the UV barrier layer, using a photomask to lithographically pattern the second photoresist layer so that second photoresist layer remains on the UV barrier layer whilst exposing portions of the UV barrier layer on opposite sides of the at least one cavity, removing the exposed portions of the UV barrier layer so as to expose portions of the first photoresist layer on opposite sides of the at least one cavity and leave remaining UV barrier layer traversing therebetween, removing the exposed portions of the first photoresist layer so as to expose the portions of the one or more layers of graphene and leave remaining first photoresist layer traversing therebetween.

9.-11. (canceled)

12. The method of claim 1, wherein forming conductive contacts comprises depositing conductive material onto the exposed portions of graphene by thermal evaporation, and wherein the conductive material comprises a layer of a first conductive material and a layer of a second conductive material.

13. The method of claim 12, wherein the first conductive material comprises Cr and/or wherein the second conductive material comprises Au.

14. The method of claim 8, wherein forming conductive contacts comprises depositing conductive material onto the exposed portions of graphene by thermal evaporation, and the method further comprises using a third photoresist layer to mask the conductive material deposited on the exposed potions of graphene, removing any other deposited conductive material, and lithographically removing the third photoresist layer prior to removing the UV barrier layer.

15.-20. (canceled)

21. The method of claim 1, wherein the at least one cavity is a single cavity or an array of adjacent cavities.

22. A method of manufacturing a graphene-based device, comprising:
providing a graphene assembly comprising one or more layers of graphene, and a first photoresist layer disposed on the one or more layers of graphene, transferring the graphene assembly onto a substrate comprising at least one cavity so that the one or more layers of graphene traverse the at least one cavity;
transferring the graphene assembly onto a substrate comprising at least one cavity so that the one or more layers of graphene traverse the at least one cavity;
using photolithography to expose portions of the graphene on opposite sides of the at least one cavity;
forming conductive contacts over the exposed portions of graphene; and
removing the first photoresist layer;
wherein removing the first photoresist layer comprises using critical point drying or immersing the device in a solvent which is then replaced with a low surface tension solvent.

23. The method of claim 22, wherein providing the graphene assembly comprises providing a precursor graphene assembly, wherein the precursor graphene assembly comprises the graphene assembly and a layer of copper disposed on a side of the one or more layers of graphene that is opposite to the first photoresist layer, and wherein the layer of copper is removed to provide the graphene assembly.

24.-26. (canceled)

27. The method of claim 22, wherein the substrate comprises of Si, SiO₂, or SU8 polymer.

28. The method of claim 22, wherein using photolithography to expose portions of the graphene on opposite sides of the at least one cavity comprises disposing a second photoresist layer on the UV barrier layer, using a photomask to lithographically pattern the first photoresist layer so as to expose the portions of the one or more layers of graphene and leave remaining first photoresist layer traversing therebetween.

29. (canceled)

30. The method of claim 28, wherein forming conductive contacts comprises depositing conductive material onto the exposed portions of trraphene by thermal evaporation, and wherein the conductive material comprises a layer of a first conductive material and a layer of a second conductive material.

31. (canceled)

32. The method of claim 28, wherein forming conductive contacts comprises depositing. conductive material onto the exposed portions of graphene by thermal evaporation, and the method further comprises using a further photoresist layer to mask the conductive material deposited on the exposed potions of graphene, removing any other deposited conductive material, and lithographically removing the further photoresist layer.

33.-35. (canceled)

36. The method of claim 22, wherein the at least one cavity is a single cavity or an array of adjacent cavities.

37. (canceled)

38. A graphene-based device comprising:
a substrate comprising a plurality of cavities;
a plurality of layers of graphene, wherein each layer of graphene is disposed on the substrate and traverses at least one of the plurality of cavities; and
electrical contacts comprising conductive material disposed on the layers of graphene on opposite sides of each of the plurality of cavities.

39. The graphene-based devices according to claim 38, wherein the graphene-hased device forms part of a gas sensor.

40. The method of claim 1, wherein removing the first photoresist layer comprises (a) using critical point drying, or (b) immersing the device in a solvent which is then replaced with a low surface tension solvent.
